(19) United States
(12) Patent Application Publication
(10) Pub. No.: US 2003/0061564 A1
(43) Pub. Date: Mar. 27, 2003

(54) Serial data extraction using two cycles of edge information

(76) Inventor: John T. Maddux, Folsom, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/965,229

(22) Filed: Sep. 27, 2001

(51) Int. Cl. H03M 13/00; G06F 11/00

(52) U.S. Cl. 714/798; 714/709

(57) ABSTRACT

One aspect of the invention provides a novel scheme to improve channel jitter tolerance and perform data recovery across a serial data channel. In one implementation, the invention samples each data unit in the data channel multiple times and, using two data cycles, selects one of the samples as representative of the data unit. According to one aspect, the invention performs edge detection between adjacent data samples to determine the location of transitions between data units (bits). A representative data sample is chosen which is as far away as possible from the detected edge and the next expected edge and yet adjacent to, or equal to, the ideal current sample point. According to another aspect of the invention, as between two equally possible samples, the algorithm selects the sample which is furthest from the distribution of prior cycle edges.

### FIELD

The invention pertains generally to serial data reception. More particularly, the invention relates to a method, apparatus, and system for extracting the correct data from a jittering data stream by using over-samples collected over two cycles.

### BACKGROUND

In serial data communication systems a typical transmitting device generates pre-specified voltage levels at a particular frequency to transmit data to a receiving device over a transmission medium. A receiving device detects the voltage levels to determine the data being sent.

One common problem that affects serial communication systems is the noise and disturbances introduced into the transmitted signal. Such noise may cause jitter (a variation in the placement of data relative to the ideal location in time) and frequency offsets (a variation in the transmission frequency) which make it difficult to correctly ascertain the data transmitted.

### BRIEF DESCRIPTION OF THE DRAWINGS

FIG. 1 is a block diagram illustrating one embodiment of a system in which a device embodying a serial channel data recovery aspect of the invention may be employed.

FIG. 2 is a block diagram illustrating one embodiment of the serial channel data recovery aspect of the invention.

FIG. 3 is a diagram illustrating sampling of a serial data stream according to one aspect of the serial channel data recovery invention.

FIG. 4 is a matrix illustrating one embodiment of a single-cycle decision matrix used to select a data sample which is representative of a data unit or bit.

FIG. 5 is a matrix illustrating one embodiment of a two-cycle decision matrix used to select a data sample which is representative of a data unit or bit according to one embodiment of the data recovery invention.

FIG. 6 is table illustrating the selection of samples under various edge transition conditions according to one embodiment of the data recovery invention.

FIGS. 7-11 illustrate various conditions under which the data recovery aspect of the invention selects a data sample based on edge transition information from two data units.

FIG. 12 is flow diagram illustrating a method of practicing data recovery according to one embodiment of the invention.

### DETAILED DESCRIPTION

In the following detailed description of the invention, numerous specific details are set forth in order to provide a thorough understanding of the invention. However, one of ordinary skill in the art would recognize that the invention may be practiced without these specific details. In other instances well known methods, procedures, and/or components have not been described in detail so as not to unnecessarily obscure aspects of the invention.

Throughout this description the terms data unit, cycle, and/or bit may be used interchangeably to refer to a single data bit or other unit of data measure.

One aspect of the invention provides a data recovery algorithm which improves data extraction from a jittering and/or frequency-offset data stream by over-sampling the data stream, determine the edges closest to the ideal current sample point, and select the actual sample point based on the previous and current data unit cycle samples.

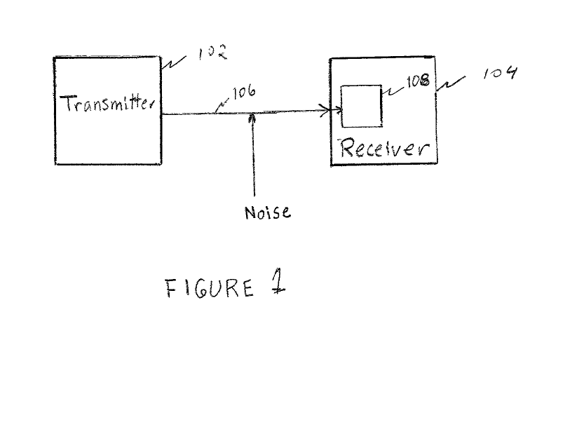

FIG. 1 illustrates a block diagram of a configuration of devices in which one embodiment of the invention may be employed. A first device 102 transmits serial data signals to a second device 104 over a transmission medium 106. The transmission medium may be susceptible to noise or interference which may cause jitter and/or frequency offsets in the transmitted signal. The second device includes a data recovery or error correction component 108 embodying one or more aspects of the invention to improve data extraction.

The component 108 embodying one or more aspects of the invention may include one or more integrated circuit devices, circuit boards, software media, and/or other electronic devices. The component 108 may be part of a communication device, network device, computing device, processing device, and/or other types of electronic devices employing some form of serial communication.

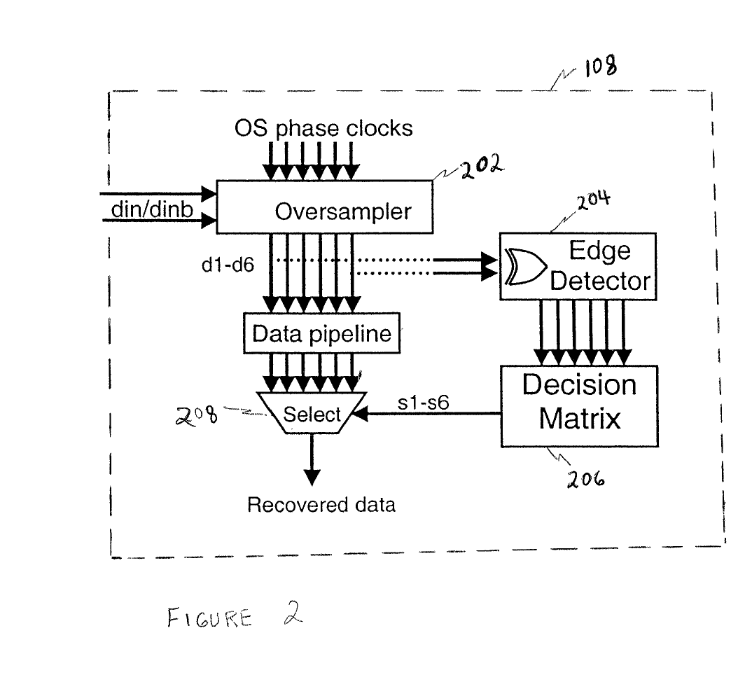

FIG. 2 is a block diagram illustrating one embodiment of the data recovery component 108 embodying one or more aspects of the invention. Clock phase over-sampling may be employed to track the incoming serial data stream and extract the correct data. According to one implementation, the data recovery system 108 includes an over-sampler 202 to receive a serial digital data stream as input and provide two or more samples (i.e., d1-d6) per signal cycle or data bit. For the exemplary embodiment shown in FIG. 2 six data samples d1-d6 serve as inputs to an edge detector 204. The edge detector 204 detects edge transitions between adjacent data samples. This edge information is then provided to a decision matrix component 206 which selects the best point from which to determine the data or bit. A selector 208 may be coupled to the over-sampler 202 to receive the sampled data; the decision matrix component 206 then causes the selector 208 to output only that sample which the decision matrix 206 selects.

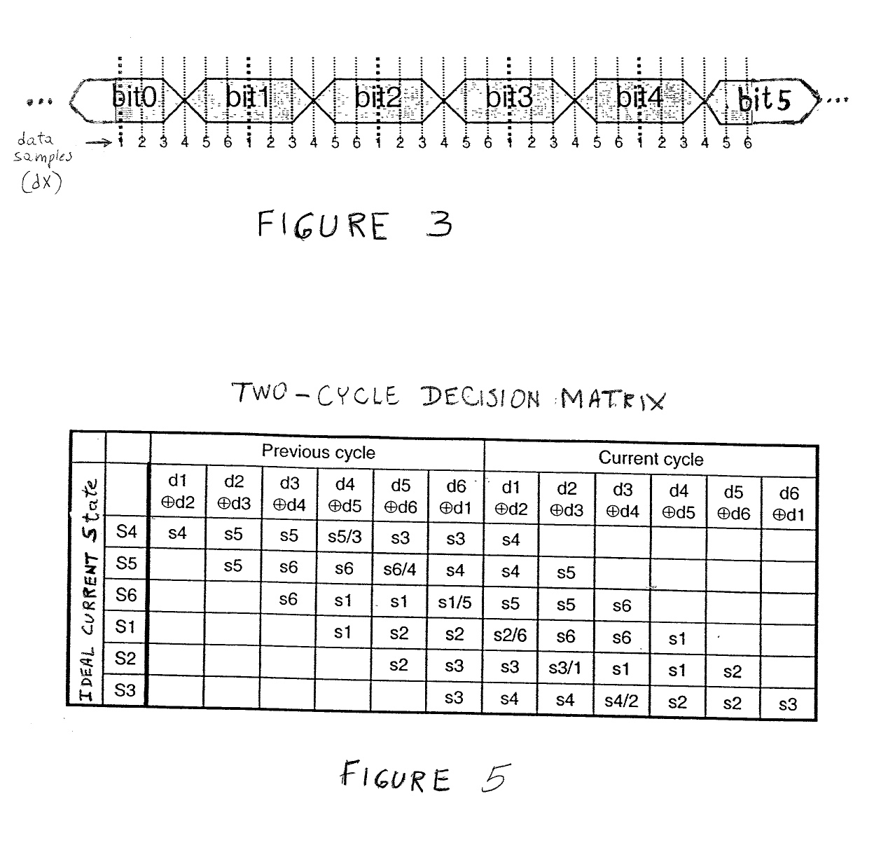

FIG. 3 provides an illustration of one embodiment of an incoming serial data stream (bit0, bit1, . . . , bit5) and six samples (six times over-sampling) for each data unit, bit, or cycle of the data stream. According to one implementation, six separate phases of a clock are used to independently sample the data stream.

Although for purposes of illustration FIG. 3 shows each data unit being sampled six times (six times over-sampling), the invention is not limited to a six time over-sampling scheme. A person of ordinary skill would appreciate that the invention may be practiced with fewer or greater number of samples per data unit. In various embodiments, a data unit may be sampled an even or odd number of times without departing from the invention.

The edge detector attempts to find the location of the edges (i.e. low-to-high or high-to-low transitions) between data bits. In one implementation, the edge detector extracts edge locations from the samples by XORing (performing exclusive OR logic operations) on adjacent data samples. For the exemplary embodiment shown in FIG. 2, six samples serve as inputs to the edge detector and the edge detector generates six outputs, each output being obtained by XORing adjacent samples. For instance, in FIG. 3 for bit3, XORing of sample pairs d4 (between bit2 and bit3) and d5, d5 and d6, d6 and d1, d1 and d2, d2 and d3, and d3 and d4 (between bit3 and bit4) would provide the six outputs for the edge detector.

Throughout this description, the symbol ⊕ is employed to refer to a XORing (exclusive OR) operation or any collection of operations which provide an equivalent result.

For each cycle, the edge detector generates the location where the edges occurred between samples. For example, if data sample d3 was logic low (0), and data sample d4 was logic high (1), the edge detector would indicate an edge occurred between d3 and d4.

A decision matrix component is coupled to the edge detector to receive the outputs from the edge detector and select one of the sample points according to a predefined decision algorithm, table, or matrix.

In the absence of jitter, the data edge would consistently be detected at the same location, for example d1⊕d2. In the presence of jitter, however, over time the data edge may move around. With a small amount of jitter, the edge may appear at two locations—i.e. d1⊕d2 and d2⊕d3. With a larger amount of jitter, the edge may occur across four locations—i.e. d6⊕d1, d1⊕d2, d2⊕d3, and d3⊕d4.

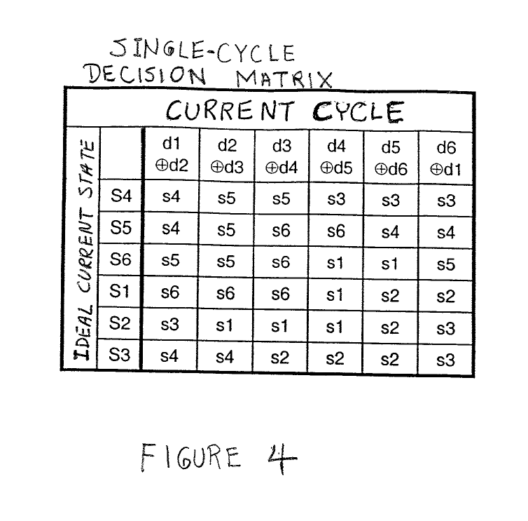

FIG. 4 illustrates a single cycle decision matrix with six possible edge transition inputs (d1⊕d2 . . . d6⊕d1) for the ‘next’ cycle and the ideal current state input. By locating a transition edge and knowing the current cycle, the ‘next’ state is selected.

Note that throughout this description the terms ‘previous state’, ‘previously selected state’, and ‘previously selected sample’ are used interchangeably to refer to the state or sample selected in the previous data unit cycle. The terms ‘ideal sample’, ‘ideal sample point’, ‘ideal state’, ‘ideal current state’, and ‘ideal current sample’ are used interchangeably to refer to the sample or state in the current data unit cycle which would be selected under ideal conditions. The ideal sample point is the data sample or state which would be selected if no jitter occurs between the previous and current data unit cycles. If no jitter occurs between data unit cycles, the ideal data sample would be at the same location as in the previous data unit cycle. For example, if the currently selected state is S1 (S1 was the selected state in the previous data unit cycle), s1 would be selected as the next state in the current data unit cycle under ideal conditions (no jitter).

Since FIG. 4 illustrates a single-cycle decision matrix, the closest edge information to the ideal sample point is not being used to determine the direction in which to shift to select the next state. For example, if the ideal current state (corresponding to the previous selected state) is S1, edges that occur on d5⊕d6 are used to determine the next state S2. But data samples d5 and d6 are the last two samples in the current cycle (data unit) and the sample corresponding to ideal current state 91 is the first sample point in the current cycle. Because of its long distance from the ideal sample point S1, the edge at d5⊕d6 in the current data cycle does not provide the most accurate or reliable transition edge from which to determine the next state.

However, the d5 and d6 samples from the previous data unit cycle are located closer to the ideal sample state or point S1. Hence, it would be better to use these earlier samples to make a decision about the next sample point.

Because the samples d5 and d6 in the previous data cycle provide the closest edge to the ideal state S1, they provide the most accurate and reliable information about the next state.

An aspect of the invention provides a decision matrix which is tolerant to high-frequency jitter.

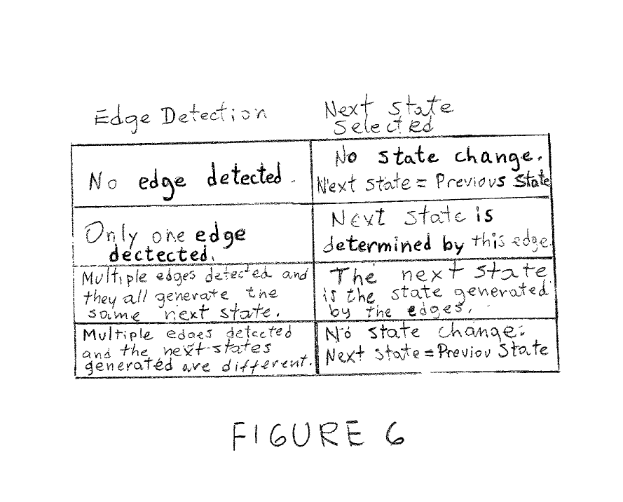

One aspect of the invention provides a method or algorithm to select which of the data samples is the best sample to use for extracting the correct data from the data stream. One embodiment of this method is shown in FIG. 5 illustrating a decision matrix where two data cycles, the previous and current data cycles, and the previous selected state (equivalent to the ideal sample point) are employed by the decision matrix to select the next best state.

The decision matrix contains a single ideal current state variable (S1 through S6) that points to the sample that is currently the best sample (ideal sample point). For example, a state of s1 indicates that sample d1 is the best sample, s2 indicates d2 is the best sample, and so on. The decision matrix uses the ideal current state, one of S1 through S6, and the edge locations detected in the current and previous data unit cycles to determine the next best state. As illustrated above, and explained in more detail below, the decision matrix seeks to determine the next best state by selecting the closest transition edge to the ideal current state from among the current and previous data cycles. Decision matrixes employing both the current and previous cycles improve jitter tolerance of an incoming serial data stream.

As illustrated in FIG. 5, for each of the six ideal current states there are five edges that are used to determine what the next state will be. For examples, if the current state is S6, then the edges generated by the previous cycle samples d4⊕d5, d5⊕d6, and d6⊕d1, and the current cycle samples d1⊕d2 and d2⊕d3 will be used to determine the next state.

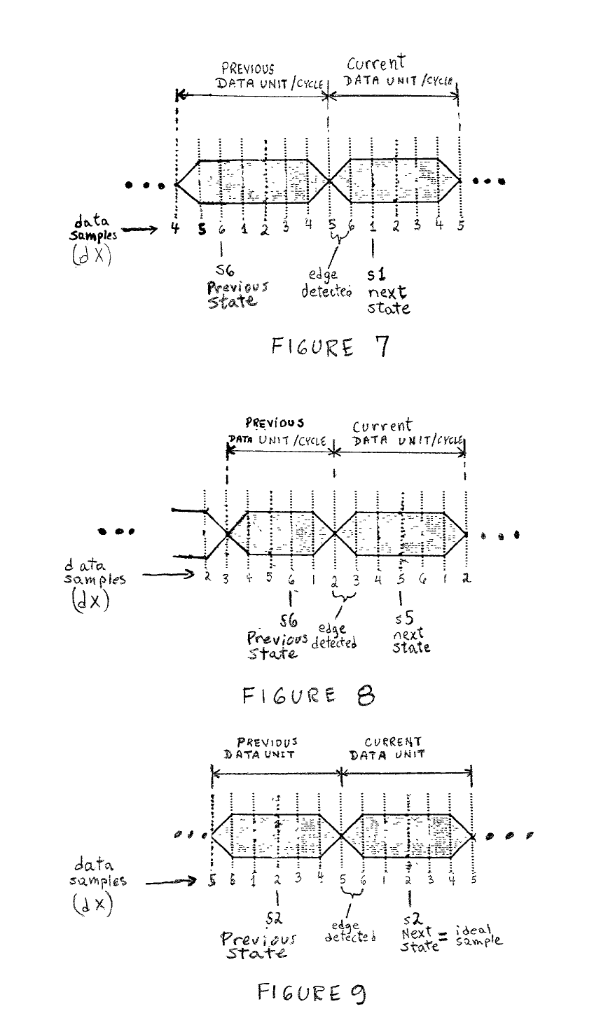

Referring to FIG. 6, if no edge is detected on any of these five edges then no state change is made; the next state is the ideal state (equivalent to the previously selected state). If a single edge is detected on one of these five edges, then the next state is determined by that edge. If more than one edge is detected on more than one of these five edges and they all generate the same next state, then that next state will be used. Finally, if more than one edge is detected on more than one of these five edges and the next state generated by these edges are different, then there is a conflict and the next state will be the same as the ideal current state (equivalent to the previously selected state in the previous data unit cycle).

According to another implementation, if more than one edge is detected and different states are generated, then the state which was generated by the most number of edges is selected as the next state. For example, if two edges generate state s1 and one edge generates s2, then the next state will be s1.

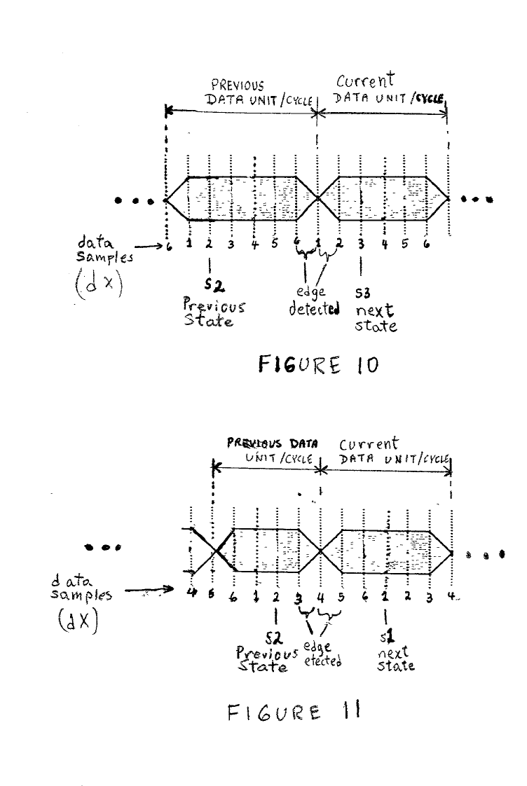

In more detail, referring to FIG. 7, if the ideal current state or sample is S6 and d5⊕d6 is true (an edge transition was detected) but no other edges were detected, then the next state is s1. Similarly, referring to FIG. 8, if the ideal current state is S6 and d2⊕d3 true and no other edges were detected, then the next state is s5. Also, if the ideal current state is S6 and both d2⊕d3 and d1⊕d2 are true, the next state is s5. However, if the ideal current state is S6 and both d5⊕d6 and d2⊕d3 are true, then there is a conflict and the next state will stay at s6.

Thus far, the next state has been selected from among the two states adjacent to the ideal current state or the ideal current state itself. For example, if the ideal current state is S2, then the next state will be either s1, s2, or s3 as determined by the matrix. Additionally, a study of the exemplary matrix in FIG. 5 discloses that the next state is chosen to be as far as possible from the detected edge and the next expected edge and yet adjacent to, or equal to, the ideal current state. That is, the decision matrix is coded so that the state pointer to next state moves away from the data samples that are close to an edge. A state or sample point is selected which lies substantially midway (or in the direction of the mid-point) between the detected edge and the next expected edge and yet is adjacent to, or equal to, the ideal current state. Note that for a system which samples each data unit (bit) N times (where N is an integer value), the next edge is expected to lie a distance of N samples from the detected edge. In the examples of FIGS. 7 & 8 the value of N is six since each data unit is sampled six times at different locations or points.

For example, referring to FIG. 9, if the ideal current state is S2 and the only edge detected is at d5⊕d6 (either in the previous cycle or next cycle), then, state s2 is selected since it lies between the two edges (previous d5 and current d5). Note that in this example, the edge is assumed to lie at d5; since d2 is equidistant between two d5 samples, s2 is selected as the best state or sample. Similarly, referring to FIG. 10, if the ideal current state or sample is S2 and the only edge detected is at d6⊕d1 or d1⊕d2, then the next state or sample is selected to be s3 since it is the furthest state or sample from s6 or s1, respectively, yet adjacent to s2. Also, referring to FIG. 11, if the ideal current state or sample is S2 and the only edge detected is at d3⊕d4 or d4⊕d5, then the next state or sample is selected to be s1 since it is the furthers state from s3 or s4, respectively, yet adjacent to the ideal current state S2.

A person of ordinary skill in the art would recognize that decision matrixes for any number of states may be created as described above.

A conditional state occurs were two states are equally likely under the algorithm described above. For example, if the ideal current state is S2 and d2⊕d3 is the only edge, then s3 and s1 are equally likely. According to one implementation, one of the two possible states is chosen arbitrarily when this condition occurs.

Another aspect of the invention provides a method, system, or algorithm to decide between two equally likely states. That is, where a conditional state occurs (i.e., where both s1 and s3 are equally likely) then the decision matrix looks at the distribution of previous edges to select the best next state from among the two choices. As between two possible next states, the algorithm selects the state which is furthest from the distribution of prior cycle edges.

For example, in a low jitter channel edges may occur only on d1⊕d2 and d2⊕d3. Based on the decision matrix in FIG. 5, with edges only at d1⊕d2 and d2⊕d3 the state pointer will converge and alternate between s4 and s5. Assuming the incoming jitter increases, transitions may now occur across four edge locations, i.e. d6⊕d1, d1⊕d2, d2⊕d3, and d3⊕d4. If at least three d6⊕d1 edges in a row occur, the state pointer either will move from s4 to s3 or from s5 to s4 and then to s3 (depending on whether it started in s5 or s4). In either case the current state pointer will be S3 and the previous state will be S4. With the current state of S3, if the next edge detected is d3⊕d4 then the next state is either s2 or s4. However, it is undesirable to select s2 because data sample d2 is right in the middle of the distribution of edges—recent edges were on d6⊕d1, d1⊕d2, d2⊕d3, and d3⊕d4. The fact that d2 is located in the middle of recent previous edges (or within the distribution of previous edges) increases the likelihood that s2 may be an erroneous reading. Rather, an algorithm of the invention would select s4 as the next state in this case. State s4 is more desirable than s2 because data sample d4 is on the far right-hand edge of the recent edges and is more likely to have the correct data. According to one implementation, state s4 would be selected since the previous state was s4. That is, as between two possible states (i.e., s2 or s4) the algorithm would select the state which was most recently selected in previous data cycles. In the example above, previous states would include S5, S4, and S3, from earliest to most recent, in that order. As between states s2 and s4, state s4 was most recently selected so it would be selected in this case.

In another example, if a transition is detected at d1⊕d2 (current state S1) the two possible states are s2 or s6. If the previous states include, from earliest to most recent, S3, S2, S1, S6, and S1, then s6 would be selected as the next best state or sample since, as between S2 and S6, S6 was the most recently selected state.

Thus, where a choice must be made between two possible states, the invention selects the most recent state to have been selected from among the two possible states or, equivalently, select the state located furthest from the most recent previous edges (or within the distribution of previous edges). Such selection algorithm has shown to increase jitter tolerance of an incoming serial data stream. In one implementation, the invention may retain memory of the previous M selected states so that a decision between two possible states may be made. In various implementations, the number of previous edges employed to make such decision may vary.

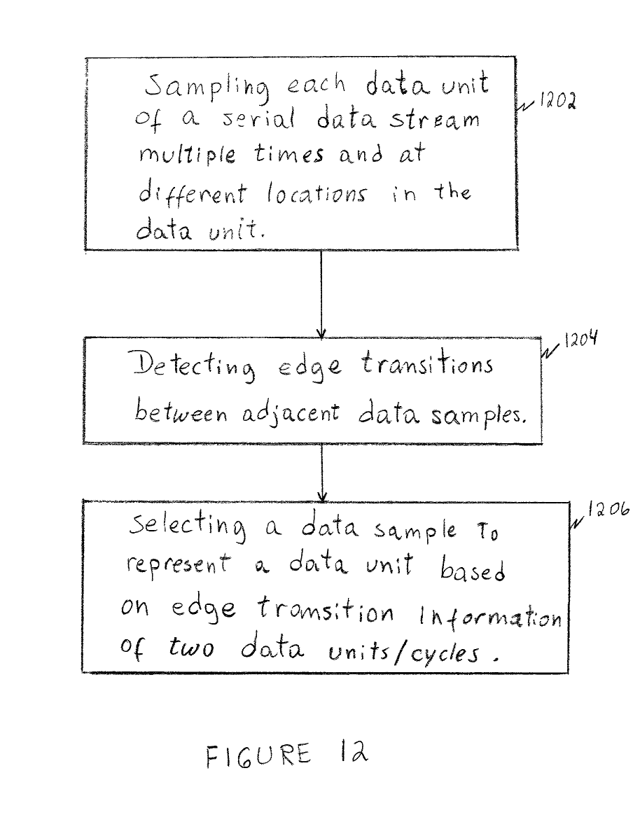

FIG. 12 illustrates one method of practicing the data recovery aspect of the invention. Each data unit (bit) across a serial data channel is sampled multiple times, at different locations along its cycle 1202. These samples are then employed to determine edge transitions between adjacent data samples 1204. One of the data samples is then selected as representative of a data unit based on the edge transition information for two data units/cycles (i.e. the current data cycle and the previous data cycle) 1206.

According to one implementation, the serial data stream received by a device embodying the invention may be a Universal Serial Bus (USB) compliant data stream, a Serial Advanced Technology Attachment (ATA) compliant data stream, and/or many other types of serial communication channels.

A person of ordinary skill in the art would recognize that there are other benefits to the invention herein disclosed. For example, while some data recovery systems may gather edge information over five (5) cycles and perform a histogram of this data to determine an optimal sample point, such architecture must store much more information than the disclosed approach. Because the invention need not store as much information as other data recovery systems, it can be implemented in a smaller area of silicon (in a chip) since less transistors are employed.

Greater or fewer sampling points may be employed in different embodiments without deviating from the invention. Although some exemplary embodiments of the invention have employed six-times (6×) over-sampling for purposes of illustration, the disclosed invention may be implemented at any other level of over-sampling without deviating from the invention.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art. Additionally, it is possible to implement the invention or some of its features in hardware, programmable devices, firmware, software or a combination thereof. The invention or parts of the invention may also be embodied in a processor readable storage medium or machine-readable medium such as a magnetic, optical, or semiconductor storage medium.

What is claimed is:

1. A method comprising:
receiving a serial data stream;
sampling each data unit in the data stream N times to obtain multiple data samples per data unit;
detecting edge transitions between adjacent data samples; and
selecting a data sample representative of the current data unit based on the location of edge transitions over the current and previous data cycles and the location of the ideal data sample to perform data recovery.

2. The method of claim 1 wherein the selected data sample is determined by the edge transition in the previous or current data cycles which is closest to the ideal data sample.

3. The method of claim 1 wherein the N samples per data unit are taken at different locations along the cycle of each data unit.

4. The method of claim 1 wherein the ideal data sample is within the current data unit cycle and N samples from the previously selected data sample.

5. The method of claim 1 wherein selecting the data sample includes,
selecting the data sample to lie in the direction of the mid-point between the detected edge transition and the next expected edge transition and a distance of N−1, N, or N+1 samples from the previously selected data sample, whichever is closest to the mid-point.

6. The method of claim 1 wherein selecting a data sample based on the location of edge transitions over two data cycles includes selecting a data sample based on 2*N consecutive data samples across the current data unit cycle and the previous data unit cycle.

7. The method of claim 1 wherein if no edge transitions are detected the selected data sample is the ideal data sample.

8. The method of claim 1 wherein if only one edge transition is detected, that edge transition determines the next selected data sample.

9. The method of claim 1 wherein if multiple edge transitions are detected and all correspond to the same data sample, then that data sample is selected.

10. The method of claim 1 wherein if multiple data edge transitions are detected and they correspond to different data samples, then the selected data sample is the ideal data sample.

11. The method of claim 1 further comprising:
maintaining a list of the M previous selected data samples, where M is an integer value.

12. The method of claim 1 wherein in selecting the data sample, as between two equally likely data sample locations, the data sample location most recently selected in previous cycles is chosen.

13. An apparatus comprising:
a sampling device to sample each data unit of a serial data stream N times at different points in each data unit, where N is an integer value;
an edge detector coupled to the sampling device to detect edge transitions between consecutive data samples; and
a selection controller coupled to the edge detector to receive the outputs from the edge detector and select a data sample to represent the current data unit according a predefined decision algorithm for data correction employing the current and previous data unit cycles and the ideal current data sample.

14. The apparatus of claim 13 wherein the ideal current data sample is located within the current data unit cycle and N samples from the selected data sample in the previous data unit cycle.

15. The apparatus of claim 13 wherein the value of N is six.

16. The apparatus of claim 13 wherein the selection controller selects the data sample corresponding to the edge transition in the previous or current data cycles which is closest to the ideal current data sample.

17. The apparatus of claim 13 wherein the selection controller selects the data sample to lie in the direction of the mid-point between the detected edge transition and the next expected edge transition and a distance of −1, 0, or +1 samples from the ideal data sample location, whichever is closest to the mid-point.

18. The apparatus of claim 13 wherein if no edge transitions are detected by the edge detector, the selection controller selects the ideal data sample location to obtain the data sample.

19. The apparatus of claim 13 wherein if only one edge transition is detected by the edge detector then the selection controller selects a sample which lies in the direction of the mid-point between the detected edge transition and the next expected edge transition and a distance of −1, 0, or +1 samples from the ideal data sample location, whichever is closest to the mid-point.

20. The apparatus of claim 13 wherein if multiple edge transitions are detected by the edge detector and all transitions correspond to the same data sample, then the selection controller selects that data sample as the next data sample.

21. The apparatus of claim 13 wherein if multiple data edge transitions are detected by the edge detector and they correspond to different data samples, then the selection controller selects the data sample corresponding to ideal data sample location.

22. The apparatus of claim 13 further comprising:
a storage device to maintaining a list of the M previous selected data samples, where M is an integer value.

23. The apparatus of claim 13 wherein, as between two equally likely data sample locations, the selection controller selects the data sample location most recently selected in previous cycles.

24. A machine-readable medium having one or more instructions to perform data recovery, which when executed by a processor, causes the processor to perform operations comprising:
sampling each data unit in a data stream N times, where N is an integer value, at different locations along the data unit, to obtain multiple data samples per data unit;
detecting edge transitions between adjacent data samples; and
selecting a data sample representative of the current data unit based on the location of edge transitions over the previous and current data cycles and the location of the ideal current data sample to perform data recovery.

25. The machine-readable medium of claim 24 wherein the representative data sample is selected to lie in the direction of the mid-point between the detected edge and the next expected edge and yet is adjacent to, or equal to, the ideal current data sample location within the current data unit cycle.

26. The machine-readable medium of claim 24 wherein if no edge transitions are detected the selected data sample corresponds to the same location as the ideal current data sample.

27. The machine-readable medium of claim 24 wherein if only one edge transition is detected, then that edge transition determines the next selected data sample to be a sample which lies in the direction of the mid-point between the detected edge transition and the next expected edge transition and a distance of −1, 0, or +1 samples from the ideal current data sample location, whichever is closest to the mid-point.

28. The machine-readable medium of claim 24 wherein if multiple edge transitions are detected and all correspond to the same data sample, then that data sample is selected.

29. The machine-readable medium of claim 24 wherein if multiple data edge transitions are detected and they correspond to different edge transitions, then the selected data sample is the same as the ideal current data sample.

30. The machine-readable medium of claim 24 wherein selecting the data sample, as between two equally likely data sample locations, the data sample location most recently selected in previous cycles is chosen.
